(19) United States
(12) Patent Application Publication
(10) Pub. No.: US 2012/0170232 A1
(43) Pub. Date: Jul. 5, 2012

(54) ELECTRONIC TEXTILE WITH LOCAL ENERGY SUPPLY DEVICES

(75) Inventors: Rabin Bhattacharya, Eindhoven (NL); Koen Van Os, Eindhoven (NL); Guido Lamerichs, Eindhoven (NL)

(73) Assignee: KONINKLIJKE PHILIPS ELECTRONICS N.V., EINDHOVEN (NL)

(21) Appl. No.: 13/393,836

(22) PCT Filed: Sep. 17, 2010
(86) PCT No.: PCT/IB10/54221

§ 371 Date: Mar. 2, 2012

(30) Foreign Application Priority Data
Sep. 24, 2009 (EP) 09171175.4

(51) Int. Cl. H05K 1/03

(52) U.S. Cl. 361/749

(57) ABSTRACT

An electronic textile (1) comprising: a textile substrate (3) comprising at least one textile substrate conductor (8a-b); and a plurality of electronic energy consuming devices (4) arranged on the textile substrate (3), each of the electronic energy consuming devices (4) being electrically connected to the at least one textile substrate conductor (8a-b) for supply of electrical power to the electronic energy consuming devices (4) from a main power supply (7). The electronic textile (1) further comprises a plurality of local energy supply devices (5a-d; 12a-d; 13a-d), arranged on the textile substrate (3), each of the local energy supply devices (5a-d; 12a-d; 13a-d) being arranged to supply electrical power to at least one of the electronic energy consuming devices (4) being associated with the local energy supply device (5a-d; 12a-d; 13a-d), in addition to electrical power supplied by the main power supply (7).

### FIELD OF THE INVENTION

The present invention relates to an electronic textile comprising a textile substrate and a plurality of electronic energy consuming devices arranged on the textile substrate.

### BACKGROUND OF THE INVENTION

Currently, research in the field of electronic textiles is very active, and although not a great deal of advanced electronic textile products can be found in the marketplace today, it is expected that many new products will find their way to the consumers in the near future.

Due to the textile-like mechanical properties that an electronic textile is expected to have, the selection of electrical conductors for interconnecting electronic devices comprised in the electronic textile is limited.

In particular, electrical conductors that are suitable for use in electronic textiles typically has a relatively low conductivity, which may lead to substantial differences in the voltage supplied to the individual electronic devices comprised in the electronic textile, resulting in non-uniform performance of the electronic textile.

### SUMMARY OF THE INVENTION

In view of the above-mentioned and other drawbacks of the prior art, a general object of the present invention is to provide an improved electronic textile, in particular an electronic textile with improved uniformity in the voltage supplied to electronic energy consuming devices comprised therein.

According to a first aspect the present invention provides an electronic textile comprising: a textile substrate comprising at least one textile substrate conductor; a plurality of electronic energy consuming devices arranged on the textile substrate, each of the electronic energy consuming devices being electrically connected to the at least one textile substrate conductor for supply of electrical power to the electronic energy consuming devices from a main power supply; and a plurality of local energy supply devices arranged on the textile substrate, each of said local energy supply devices being arranged to supply electrical power to at least one of the electronic energy consuming devices being associated with the local energy supply device, in addition to electrical power supplied by the main power supply.

By “textile” should, in the context of the present application, be understood a material or product manufactured by textile fibers. The textile may, for example, be manufactured by means of weaving, braiding, knitting, crocheting, quilting, or felting. In particular, a textile may be woven or non-woven.

The at least one textile substrate conductor comprised in the textile substrate may be provided on the surface of the textile substrate, or may be a structural component of the textile substrate.

When being provided on the surface, the electrical conductor(s) may, for example, be formed by a conductive substance that may be applied to the textile substrate. Such a conductive substance may, for example, be a conductive glue or a conductive ink. The conductive substance may, for instance, be applied to the textile substrate using dispensing techniques, printing (including screen printing and inkjet printing), or painting using a suitable brush or similar.

The main power supply may be comprised in the electronic textile, or may be an external device.

The present invention is based on the realization that voltage drop in the textile substrate conductor(s) can be compensated for by providing local energy supply devices that supplement the main power supply to locally boost the voltage, whereby the spatial uniformity in the performance of the electronic textile can be improved.

To efficiently address the uniformity problem associated with the relatively high resistance of the textile substrate conductor(s), the local energy supply devices may advantageously be distributed across the textile substrate in such a way that each local energy supply device has a set of electronic energy consuming devices that “belongs” to the local energy supply device. The set of electronic energy consuming devices that belongs to, or is associated with, a given local energy supply device may advantageously be that or those electronic energy consuming device(s) arranged closest to the local energy supply device. In particular, the set of electronic energy consuming devices that belongs to, or is associated with, a given local energy supply device may advantageously be that or those electronic energy consuming device(s) arranged within 5 m from the local energy supply device in terms of the length of the textile substrate conductor used for conducting the current from the local energy supply device to the electronic energy consuming devices.

Through the provision of such local energy supply devices, it becomes generally possible to provide larger electronic textiles with acceptable spatial uniformity. Furthermore, the distance between individual electronic energy consuming devices can be increased while achieving an acceptable spatial uniformity of the electronic textile.

It should be noted that each of the local energy supply devices may advantageously be dimensioned in such a way that the local energy supply device is unable to independently supply the electrical power required for operation of the at least one electronic energy consuming device being associated with the local energy supply device. Accordingly, the local energy supply devices may be relatively small and cheap and still be capable of providing sufficient electrical power to locally supplement the electrical power provided by the main power supply and thereby improve the spatial uniformity of the distribution of electrical power in the electronic textile.

According to various embodiments, the electronic energy consuming devices may be connected in parallel between at least two textile substrate conductors.

Moreover, the electronic textile may comprise at least three electronic energy consuming devices, each being arranged on the textile substrate and being electrically connected to the at least one textile substrate conductor.

Furthermore, each local energy supply device may be integrated with the at least one electronic energy consuming device being associated therewith. Accordingly, at least one of the local energy supply devices and at least one of the electronic energy consuming devices may be integrated to form a single device being arranged on the textile substrate.

According to one embodiment, the textile substrate may be a ribbon. The ribbon may be manufactured using any suitable textile production technique, such as weaving, knitting, braiding or crocheting.

Furthermore, the at least one electrical conductor comprised in the textile substrate may be a conductive yarn. This may typically be the case when the textile substrate is manufactured using yarns, that is, using techniques such as the above-mentioned weaving, knitting or braiding. One or several conductive yarns may also be stitched to the textile substrate, which means that the textile substrate may also be made of a so-called “non-woven” material.

Depending on the application, the conductive yarn may have an electrically conductive outer surface. Such a yarn will be easier to connect electronic components etc to than a yarn having an insulating sheath, but to avoid short-circuits where this is not intended, conductive yarns should be separated from each other, for example by non-conductive yarns.

A “yarn” is generally defined as a long continuous length of interlocked fibers or filaments, suitable for use in the production of textiles, sewing, crocheting, knitting, weaving, embroidery and rope making.

A “conductive yarn” is a yarn that is capable of conducting electric current. This can be achieved by providing a yarn with one or several conductive filament(s), or coating a non-conductive yarn with a conductive coating.

According to various embodiments, each of the electronic energy consuming devices may advantageously include a light-emitting device, such as a light-emitting diode. Hereby, a light-emitting electronic textile with an improved spatial uniformity of the emitted light can be achieved.

Furthermore, each of the local energy supply devices may be configured to sense a local voltage level provided by the at least one textile substrate conductor to the electronic energy consuming device being associated with the energy supply device; and supply electrical power to the electronic energy consuming device being associated with the local energy supply device if the local voltage level is below a predetermined threshold level.

The voltage distribution across the electronic textile may vary dynamically, depending on various factors, such as the number and distribution of electronic energy consuming devices that are operated, environmental conditions etc. Such dynamic variations in the voltage distribution can be handled by sensing the local voltage level and controlling the local energy supply device to locally provide electrical energy to supplement the electrical energy provided by the main power supply (boost the local voltage level) if the sensed voltage level is below a predetermined threshold level. Accordingly, an improved spatial uniformity over time can be achieved.

According to one embodiment, the local energy supply devices may be energy storage devices, such as capacitors or batteries.

Moreover, each of the energy storage devices may be electrically connected to a textile substrate conductor for charging the energy storage devices and electrically connectable to the textile substrate conductor for supply of electrical power to the electronic energy consuming devices.

Alternatively, the energy storage devices may be configured to receive and store electrical energy supplied by the textile substrate conductor that is connected to the electronic energy consuming devices when and where the local voltage is sufficiently high, and to provide stored electrical energy to the textile substrate conductor that is connected to the electronic energy consuming devices when and where the local voltage is below a threshold voltage level.

According to various embodiments, some or all of the local energy supply devices may be energy harvesting devices arranged to collect energy supplied to the electronic textile and provide the energy as electrical energy for supply to the electronic energy consuming devices.

The energy harvesting devices may be provided from a group comprising devices converting mechanical energy to electrical energy, devices converting solar radiation to electrical energy, devices converting heat to electrical energy and devices collecting static electrical charge.

For example, the energy harvesting devices may comprise solar cells, piezoelectric crystals, micro-electrical mechanical system components (MEMS-components), devices utilizing the Seebeck effect (generating electrical energy from heat) etc.

### BRIEF DESCRIPTION OF THE DRAWINGS

These and other aspects of the present invention will now be described in more detail, with reference to the appended drawings showing currently preferred embodiments of the invention, wherein:

FIG. 1a schematically illustrates an exemplary electronic textile according to an embodiment of the present invention;

FIG. 1b is an enlarged view of the electronic textile in FIG. 1a, schematically illustrating local energy supply devices comprised in the electronic textile;

FIG. 2 is an enlarged view of an exemplary electronic textile comprising local energy supply devices in the form of solar cells; and

FIG. 3 is an enlarged view of an exemplary electronic textile comprising local energy supply devices comprising capacitors.

### DETAILED DESCRIPTION OF THE EMBODIMENTS

In the following description, the present invention is described with reference to an electronic textile in the form of wearable display comprising a plurality of light-emitting diodes (LEDs) and local energy supply devices in the form of solar cells or capacitors each being arranged close to the light-emitting diode to which it is to supply electrical power. It should be noted that this by no means limits the scope of the invention, which is equally applicable to other electronic textiles comprising other kinds of energy supply devices. Furthermore, other components than LEDs may naturally be included in the electronic textile, such as various types of passive components or active components, such as sensors, actuators etc.

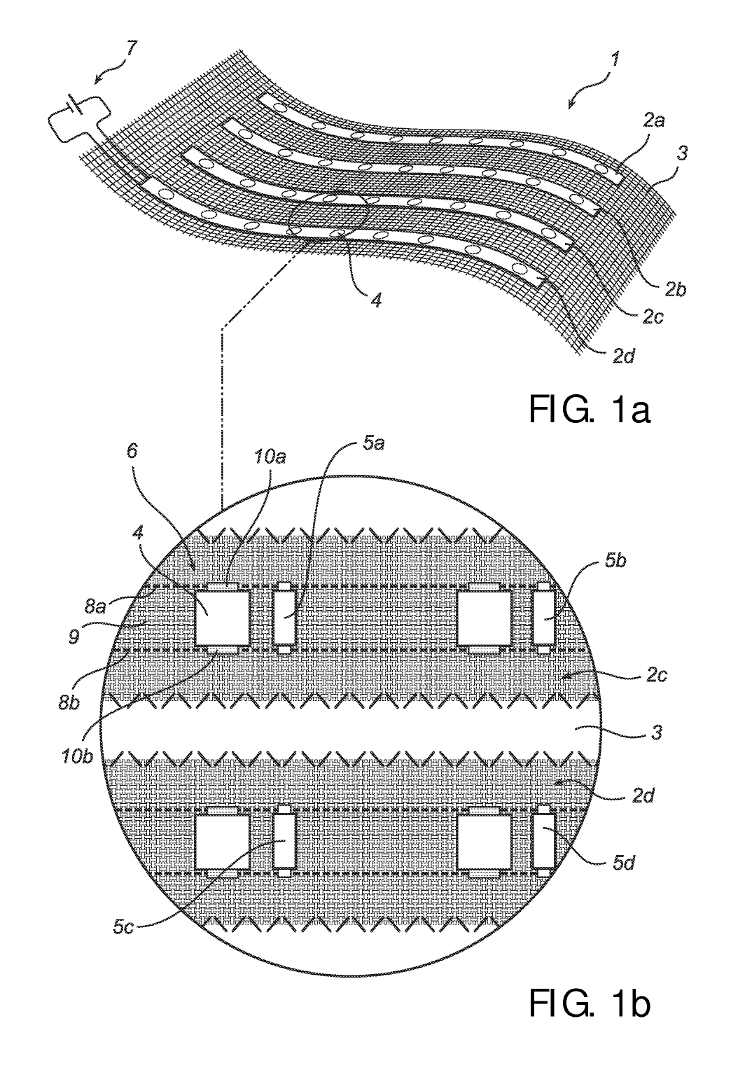

FIG. 1 a schematically illustrates a first exemplary electronic textile 1 having a plurality of segments 2a-d of a ribbon-shaped textile electronic arrangement attached to a fabric 3. In the exemplary embodiment shown in FIG. 1a, each segment 2a-d is a separate electronic textile, and each separate electronic textile comprises nine electronic components, here in the form of LEDs 4 (only one of these is indicated with a reference numeral to avoid cluttering the figure).

The electronic textile 1 in FIG. 1a may, for example, be a part of piece of clothing or similar.

When providing the electronic components 4 on separate segments 2a-d of an electronic textile attached to the fabric 3, the components 4 in each segment 2a-d may be electrically connected to a main power supply device 7 and/or a control device or similar (the latter device not being shown in the figure). The main power supply device 7 and/or the control device may advantageously be attached to the fabric 3, but may alternatively be arranged external to the electronic textile and be electrically connected thereto through suitable wiring.

As is more clearly shown in FIG. 1b, which is an enlarged view of a portion of the electronic textile 1 in FIG. 1a, the electronic textile 1 further comprises local energy supply devices 5a-d arranged close to their respective LEDs 4. Through the provision of the local energy supply devices 5a-d, the non-uniformity that may otherwise occur due to the voltage drop in the textile substrate conductors, leading to different voltages across the different LEDs 4 can be greatly reduced. The energy supply devices 5a-d may continuously supplement the electrical power supplied by the main power supply device 7 to their respective associated LEDs 4, or may be configured to monitor the voltage across their respective associated LEDs 4 and supply supplementary electrical energy only if the monitored voltage is below a predetermined threshold voltage. Of course, the voltage can be monitored directly or indirectly, by monitoring the current flowing through a reference resistor.

As can be seen in FIG. 1b, the local energy supply devices 5a-d are arranged relatively close to their respective associated electronic energy consuming devices 4. The actual distance between the local energy supply devices 5a-d and their respective associated electronic energy consuming devices 4 will depend on factors such as the allowable voltage distribution among the different electronic energy consuming devices 4, the resistivity of the textile substrate conductor (which for a conductive yarn may typically be in the range 0.1 Ω/m to 1 Ω/m) and the desired textile-like mechanical properties of the electronic textile. In practical applications where the local energy supply device and its associated electronic energy consuming device are not provided in the form of a single integrated device, the minimum distance to maintain the desired textile-like mechanical properties may for example be about 1 mm, an advantageous distance being from about 0.5 cm to about 2 cm.

The segments 2a-d are, as can be seen in FIG. 1b, provided in the form of woven ribbons 6 formed by interwoven conductive 8a-b and non-conductive 9 yarns. The conductive yarns 8a-b may have a conductive outer surface, and are not short-circuited because they are separated by several non-conductive yarns 9.

The woven ribbons 2a-d are stitched to the fabric 3 as is schematically illustrated in FIG. 1b. As will be evident to the skilled person, the ribbons can be attached to the fabric 3 in various other ways depending on application. Examples of other ways of attaching the segments 2a-d to the fabric 3 include, for example, gluing, clamping, ultrasonic welding, etc.

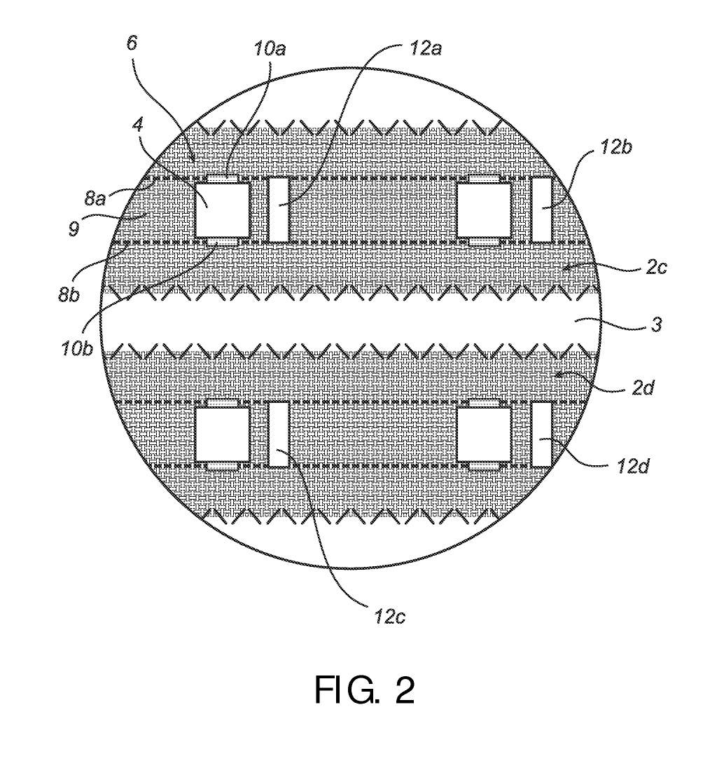

The local energy supply devices 5a-d may be realized in various different ways, and such devices can, for example, be categorized in the categories “energy storage devices” and “energy harvesting devices”. Examples of electronic textiles with local energy supply devices from these categories will now be described with reference to FIGS. 2 to 4.

FIG. 2 schematically illustrates an example of an electronic textile comprising local energy supply devices in the form of solar cells 12a-d, belonging to the category “energy harvesting devices”. The solar cells 12a-d “harvest” solar energy in the form of radiation and converts it to electricity. When the solar cells 12a-d are subjected to solar radiation, electrical energy is generated. This electrical energy may be directly fed to the associated LEDs 4 through the textile substrate conductors 8a-b. Furthermore, the solar cells 12a-d may be configured to store the generated electrical energy and supply it to the associated LEDs 4 as required. To determine when to supply electrical energy to the associated LEDs 4, the solar cells 12a-d may further be configured to monitor the voltage across the associated LEDs 4. It should be noted that the foregoing is valid for any kind of energy harvesting device and not only for the solar cells 12a-d in FIG. 2. Accordingly, any such energy harvesting device may be configured to store the generated electrical energy and/or to monitor the voltage across the associated electronic energy consuming device.

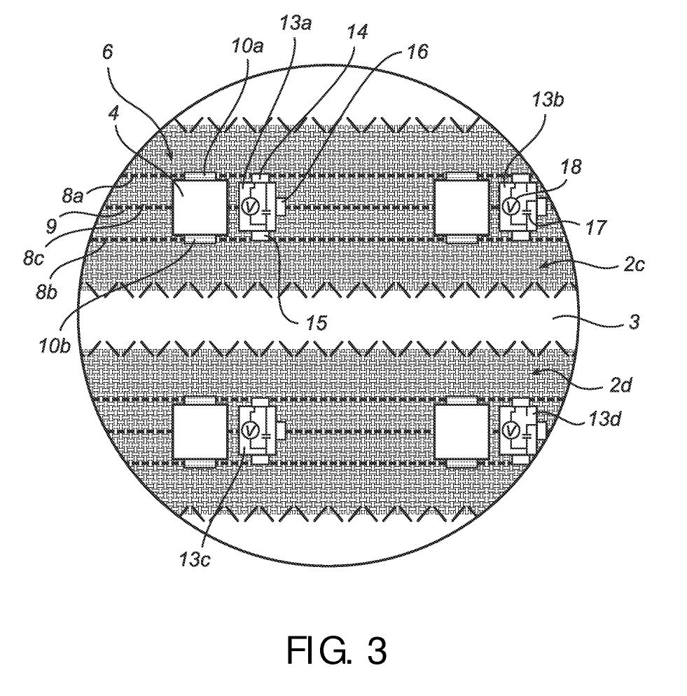

FIG. 3 schematically illustrates an example of an electronic textile comprising local energy supply devices in the form of capacitor-based devices 13a-d, belonging to the category “energy storage devices”. As is schematically shown in FIG. 3, each segment 2a-d comprises a further textile substrate conductor 8c for charging the capacitors in the capacitor-based energy supply devices 13a-d. Each capacitor-based energy supply device 13a-d has three terminals 14, 15, 16, connected to textile substrate conductors 8a-c, respectively.

As can be seen in FIG. 3, each capacitor-based energy supply device 13a-d can be switched between a storing state (capacitor-based energy supply device 13a) where the capacitor 17 is charged through the further textile substrate conductor 8c and a supply state (capacitor-based energy supply device 13b) where the capacitor 17 is connected to the textile substrate conductor 8a that supplies power to the LEDs 4 to provide local supply of power.

The switching between the storing state and the supply state may be controlled based on output from a voltage monitoring device 18 which monitors the voltage across the respective LEDs 4. In FIG. 3, local energy supply devices 13a and 13c are illustrated in their supply states, while local energy supply devices 13b and 13d are illustrated in their storing states.

The term “substantially” herein, such as in “substantially parallel”, will be understood by the person skilled in the art. Likewise, the term “about” will be understood. The terms “substantially” or “about” may also include embodiments with “entirely”, “completely”, “all”, “exactly, etc., where appropriate. Hence, in embodiments the adjective substantially may also be removed. For instance, the term “about 2°”, may thus also relate to 2°”.

The person skilled in the art will realize that the present invention is by no means limited to the preferred embodiments. For example, other types of electronic textiles than the electronic textile comprising woven ribbons as described above may advantageously be used depending on application. For instance, the woven ribbon may be replaced by a twisted yarn or a braided or knitted ribbon. The latter may be especially suitable for applications in which stretchability is desired. Moreover, the electronic energy consuming devices and the local energy supply devices may be attached directly to the fabric 3, which may be provided with a plurality of textile substrate conductors to that end. Additionally, although being described as separate components in the present description, the local energy supply devices and the electronic energy consuming devices may be provided in the form of integrated devices or components comprising several elements, such as a local energy supply device, an electronic energy consuming device such as a LED and possibly control circuitry for control of the local energy supply device and/or the electronic energy consuming device.

1. An electronic textile comprising:
a textile substrate comprising at least one textile substrate conductor (8a-b);
a plurality of electronic energy consuming devices arranged on said textile substrate each of said electronic energy consuming devices being electrically connected to said at least one textile substrate conductor for supply of electrical power to said electronic energy consuming devices from a main power supply; and
a plurality of local energy supply devices arranged on said textile substrate each of said local energy supply devices being arranged to supply electrical power to at least one of said electronic energy consuming devices being associated with said local energy supply device, in addition to electrical power supplied by said main power supply.

2. The electronic textile according to claim 1, wherein each of said local energy supply devices is dimensioned in such a way that it is unable to independently supply the electrical power required for operation of said at least one electronic energy consuming device being associated with said local energy supply device.

3. The electronic textile according to claim 1, wherein said electronic energy consuming devices are connected in parallel between at least two textile substrate conductors.

4. The electronic textile according to claim 1 comprising at least three electronic energy consuming devices each being arranged on said textile substrate and electrically connected to said at least one textile substrate conductor.

5. The electronic textile according to claim 1 wherein, for each of said local energy supply devices, said local energy supply device and said at least one electronic energy consuming device being associated with said local energy supply device are integrated to form a single device being arranged on said textile substrate.

6. The electronic textile according to claim 1, wherein at least one textile substrate conductor is a conductive yarn.

7. The electronic textile according to claim 6, wherein said textile substrate is a woven fabric formed by interwoven non-conductive yarns and conductive yarns.

8. The electronic textile according to claim 6, wherein said textile substrate is a knitted fabric comprising non-conductive yarns and conductive yarns.

9. The electronic textile according to claim 1 wherein each of said electronic energy consuming devices includes a light-emitting device.

10. The electronic textile according to claim 1, wherein each of said local energy supply devices is configured to:
sense a local voltage level provided by said at least one textile substrate conductor to said electronic energy consuming device being associated with said local energy supply device; and
supply electrical power to said electronic energy consuming device being associated with said local energy supply device if said local voltage level is below a predetermined threshold level.

11. The electronic textile according to claim 1, wherein said local energy supply devices comprise energy storage devices.

12. The electronic textile according to claim 11, wherein each of said energy storage devices is electrically connected to a textile substrate conductor for charging said energy storage device and electrically connectable to said at least one textile substrate conductor for supply of electrical power to said electronic energy consuming devices.

13. The electronic textile according to claim 1, wherein said local energy supply devices comprise energy harvesting devices arranged to collect energy supplied to said electronic textile and provide said energy as electrical energy for supply to said electronic energy consuming devices.

14. The electronic textile according to claim 13, wherein said energy harvesting devices are provided from a group consisting of devices converting mechanical energy to electrical energy, devices converting solar radiation to electrical energy, devices converting heat to electrical energy and devices collecting static electrical charge.
